(19) United States
(12) Patent Application Publication
(10) Pub. No.: US 2010/0307575 A1
(43) Pub. Date: Dec. 9, 2010

(54) SOLAR CELL AND METHOD MANUFACTURING THE SAME

(75) Inventors: Boum Seock KIM, Gyeonggi-do (KR); Hwan Soo Lee, Seoul (KR); Sang Jin Kim, Gyeonggi-do (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/511,486

(22) Filed: Jul. 29, 2009

(30) Foreign Application Priority Data
Jun. 4, 2009 (KR) 10-2009-0049482

(51) Int. Cl. H01L 31/0224; H01L 31/18

(52) U.S. Cl. 136/256; 438/72; 257/E31.124

(57) ABSTRACT

Disclosed is a solar cell and a manufacturing method thereof. The solar cell includes: a substrate; an adhesive electrode disposed on the substrate; a first electrode adhered to the substrate by the adhesive electrode; a light absorption layer disposed on the first electrode; a window layer disposed on the light absorption layer; and a second electrode disposed on the window layer.

### CROSS-REFERENCE TO RELATED APPLICATIONS

This application claims the benefit of Korean Patent Application No. 10-2009-0049482 filed with the Korea Intellectual Property Office on Jun. 4, 2009, the disclosure of which are incorporated herein by references.

### BACKGROUND OF THE INVENTION

1. Field of the Invention

The present invention relates to a solar cell, which is formed by performing a process for forming a thin-film on a sapphire substrate at a high temperature, and then performing a process for transferring the thin-film on a final substrate, and a method for manufacturing the solar cell.

2. Description of the Related Art

A solar cell includes two electrodes facing each other, and an n-type semiconductor and a p-type semiconductor interposed between two electrodes. Herein, the solar cell has electrons and holes generated within the semiconductors by light received from an outside. Such electrons and holes are moved to the n-type semiconductor and the p-type semiconductor by an electric field formed within the semiconductors and then are accumulated in each of two electrodes.

In this case, when two electrodes are electrically interconnected to each other, current flows, and the current can be used as electricity in an outside.

A CIGS-based compound semiconductor forming the solar cell is in the spotlight as a material of a next-generation solar cell because of absence of initial deterioration, as well as higher efficiency than other materials.

However, the CIGS-based compound semiconductor does not have desired light absorption until it is deposited at a high temperature, e.g. at least 600° C. or higher, which causes deformation (i.e. warpage) of a substrate used to form the CIGS-based compound semiconductor due to heat.

Thus, there was a limit in selecting materials of the substrate for forming the solar cell.

On the other hand, in a deposition process for forming the CIGS-based compound semiconductor, a top-plate deposition method for disposing a substrate on an upper part of a deposition chamber may be used. This is because the top-plate deposition method is advantageous to a large-area substrate in comparison with a bottom-plate deposition method for disposing a substrate on a lower part of the deposition chamber and it costs less to manufacture deposition equipment.

However, the CIGS-based compound semiconductor has a limitation in using the top-plate deposition method due to warpage, which is caused by a high-temperature process, so it has been deposited by the bottom-plate deposition method disadvantageous to a large-area substrate

Therefore, in the prior art, the CIGS-based compound semiconductor has been intended to be used for formation of a solar cell having superior light efficiency, but it necessitates high-temperature deposition, so there have been problems, such as warpage, manufacturing costs, and large-area of the substrate.

### SUMMARY OF THE INVENTION

The present invention has been proposed in order to overcome the above-described problems and it is, therefore, an object of the present invention to provide a solar cell, which is formed by performing a process for forming a thin-film on a sapphire substrate at a high temperature, and then performing a transfer process for transferring the thin-film on a final substrate, and a method for manufacturing the solar cell.

In accordance with one aspect of the present invention to achieve the object, there is provided a solar cell including: a substrate; an adhesive electrode disposed on the substrate; a first electrode adhered to the substrate by the adhesive electrode; a light absorption layer disposed on the first electrode; a window layer disposed on the light absorption layer; and a second electrode disposed on the window layer.

Also, the adhesive electrode is made of a metal compound containing a metal forming the first electrode.

Also, the first electrode is formed of Pd, and the adhesive electrode is formed of PdIn3.

Also, the substrate is selected from one of a glass substrate and a plastic substrate.

Also, the solar cell further includes a buffer layer interposed between the light absorption layer and the window layer.

Also, the solar cell further includes a reflection prevention film interposed between the window layer and the second electrode.

In accordance with still another aspect of the present invention to achieve the object, there is provided a method for manufacturing a solar cell including the steps of: forming a sacrificial layer on a sapphire substrate; sequentially forming a window layer, a light absorption layer, and a first electrode on the sacrificial layer; forming an adhesive electrode for adhering the first electrode to the substrate by heating a substrate including a conducive adhesive layer on the first electrode; separating the sapphire substrate including the sacrificial layer from the window layer; and forming a second electrode on the window layer exposed by the separation of the sapphire substrate.

Also, the first electrode is formed of Pd.

Also, the conductive adhesive layer is formed of In.

Also, the adhesive electrode is formed of PdIn3.

Also, the substrate is selected from one of a glass substrate and a plastic substrate.

The step of separating the sapphire substrate including the sacrificial layer from the window is achieved by irradiating laser on the sapphire substrate and the bonded substrate.

The method further includes a step of forming a buffer layer between the light absorption layer and the window layer.

The method further includes a step of forming a reflection prevention film between the window layer and the second electrode.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view illustrating a solar cell in accordance with a first embodiment of the present invention; and

FIGS. 2 to 6 are cross-sectional views illustrating a method for manufacturing a solar cell in accordance with a second embodiment of the present invention.

### DETAILED DESCRIPTION OF THE PREFERABLE EMBODIMENTS

Hereinafter, embodiments of the present invention will be described in detail with reference to the accompanying drawings illustrating a solar cell. The following embodiments are provided as examples to allow those skilled in the art to sufficiently appreciate the spirit of the present invention. Therefore, the present invention can be implemented in other types without limiting to the following embodiments. And, for convenience, the size and the thickness of an apparatus can be overdrawn in the drawings. The same components are represented by the same reference numerals hereinafter.

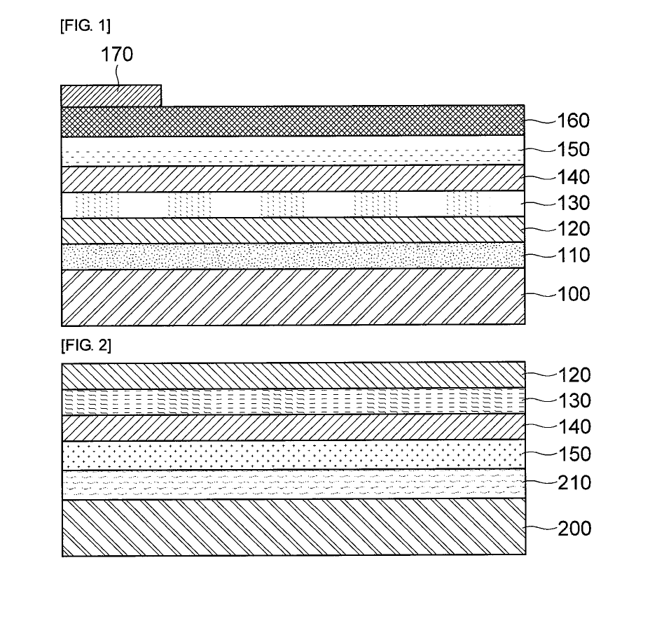

FIG. 1 is a cross-sectional view illustrating a solar cell in accordance with a first embodiment of the present invention.

Referring to FIG. 1, the solar cell in accordance with the embodiment of the present invention may include an adhesive electrode 110, a first electrode 120, a light absorbing layer 130, a window layer 150, and a second electrode 170, which are sequentially disposed on the substrate 100.

The substrate 100 may be a glass substrate or plastic substrate. Herein, the glass substrate may be a sodalime substrate made of a material cheaper than other materials. Also, the plastic substrate may be a rigid substrate or a flexible substrate. In this case, as for a material of the plastic substrate, polycarbonate, polyacryl, polyimide, polyethylene ether phthalate, polyether sulfone, and so on may be exemplified.

The adhesive electrode 110 plays a role of allowing the substrate 100 and the first electrode 120 to be adhered to each other. In this case, the adhesive electrode 110 may be made of a metal compound containing metal forming the first electrode 120. For example, in case where the first electrode 120 is formed of Pd, the adhesive electrode 110 may be formed of PdIn3.

The first electrode 120 may be formed of a metallic material which can come into ohmic contact with the light absorbing layer 130. In addition, the first electrode 120 may be formed of material which can reflect light such that light absorbed from the light absorbing layer 130 can be prevented from being transmitted. In general, the first electrode 120 may be formed of molybdenum. However, the molybdenum is difficult to be subjected to a formation process of a metal compound deposited for a transfer process. In the embodiment of the present invention, the first electrode 120 may be formed of Pd which reacts with other metal (e.g. In) to easily form a metal compound.

The light absorbing layer 130 plays a role of converting energy of light absorbed through the window layer 150 to be described into electric energy. Herein, the light absorbing layer 130 may be formed of a CIGS-based compound semiconductor transcribed as [Cu(In,Ga)(Se,S)2. The window layer 150 can absorb light and then provide effectively the light to the light absorbing layer 130. The window layer 150 may be formed of metal oxides. For example, as for a material of the window layer 150, ZnO may be used. The present invention is not limited thereto.

Further, a buffer layer 140 may be further provided between the light absorbing layer 130 and the window layer 150. The buffer layer 140 can play a role of improving adhesion between the light absorbing layer 130 and the window layer 150. Also, the buffer layer 140 may play a role of alleviating difference of energy band gap between the light absorbing layer 130 and the window layer 150. In this case, as for a material of the buffer layer 140, CdS, ZnS, and In2O3 may be exemplified.

The second electrode 170 plays a role of outputting electric energy formed by the solar cell to an external circuit, together with the first electrode 120. The second electrode 170 may be formed of double film of a conductive material which has low contact resistance, for example, Al, or Al and Ni.

For reduction in light loss between the window layer 150 and the second electrode 170, that is, for prevention of light reflection from a surface of the window layer 150, a reflection prevention film 160 may be further provided. As for a material of the reflection prevention film 160, MgF2 may be exemplified.

Hereinafter, a description will be given of a method for manufacturing a solar cell which can overcome limitation for a substrate material with reference to FIGS. 2 to 6.

FIGS. 2 to 6 are cross-sectional views illustrating a method for manufacturing a solar cell in accordance with a second embodiment of the present invention.

Referring to FIG. 2, in order to manufacture the solar cell in accordance with the embodiment of the present invention, a sapphire substrate 200 is first provided. The sapphire substrate 200 may be formed of a material which has durability against a high-temperature, e.g. deposition temperature of 600° C.

A sacrificial layer 210 is formed on the sapphire substrate 200. The sacrificial layer 210 may be formed of a material capable of being easily separated by a laser, for example, GaN, and PLZT.

The window layer 150, the light absorbing layer 130, and the first electrode 120 are sequentially formed on the sacrificial layer 210. Herein, the window layer 150 may be formed by deposition of ZnO through a sputtering method. Further, the light absorbing layer 130 may be formed of the CIGS-based compound semiconductor. Herein, the light absorbing layer 130 may be formed by co-deposition of Cu, In, Ga, Se, and so on. In this case, since the sapphire substrate 200 has durability against a deposition temperature of 600° C. or higher, deformation of the sapphire substrate 200 fails to occur in a thin-film formation process. Therefore, deposition of the light absorbing layer 130 may be achieved by using the top-plate deposition method for disposing the sapphire substrate 200 on the top part of the deposition chamber. However, the embodiment of the present invention is not limited to the deposition method for forming the light absorbing layer 130. For example, it is possible to form the light absorbing layer 130 through the bottom-plate deposition method as well.

The first electrode 120 comes into ohmic contact with the light absorbing layer 130 because of superior light reflection rate. The first electrode 120 may be formed by deposition of a metal (e.g. Pd) which can reacts with the conductive adhesive layer 230 to form a metal compound. In addition, the buffer layer 140 may be further formed between the window layer 150 and the light absorbing layer 130. Herein, the buffer layer 140 may be formed through deposition of any one of CdS, ZnS, and In2O3.

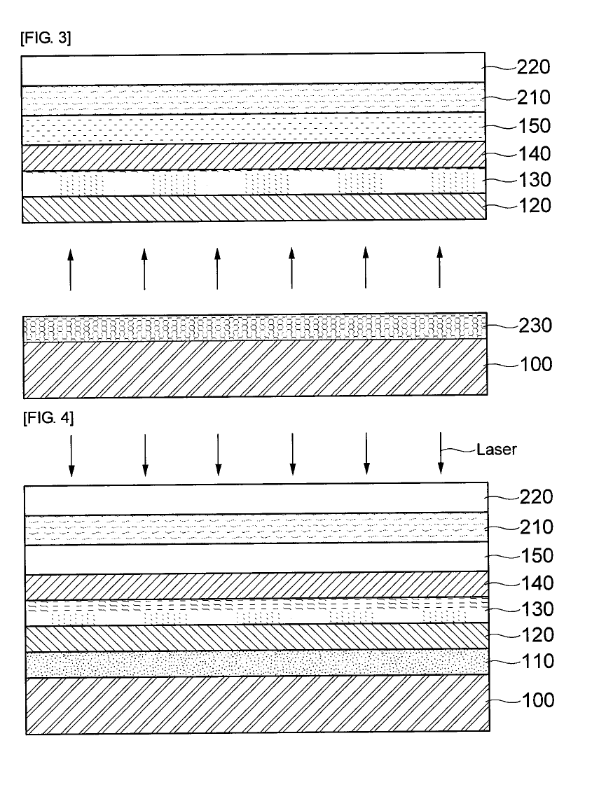

Referring to FIG. 3, a substrate 100 including the conductive adhesive layer 230 is provided on the sapphire substrate 200 including the first electrode 120. In this case, the conductive adhesive layer 230 is bonded to be opposite to the first electrode 120. The conductive adhesive layer 230 may be formed of deposition of metal (e.g. In) which can reacts the metal of the first electrode 120 through heating to form a metal compound.

The substrate 100, which is a final substrate used for the solar cell, may be a plastic substrate or a glass substrate cheaper than the sapphire substrate 200. For example, the glass substrate may be a sodalime glass substrate. Further, as for a material of the plastic substrate, polycarbonate, polyacryl, polyimide, polyethylene ether phthalate, polyether sulfo, and so on may be exemplified.

Referring to FIG. 4, the sapphire substrate 200 and the substrate 100 are heated and bonded. In this case, it is possible to form the adhesive electrode 110 that adheres the sapphire substrate 200 to the ceramic substrate 100 by reaction between a part of a metal of the first electrode 120 and a metal of the conductive adhesive layer 230 at a predetermined temperature, e.g. 200° C. in a heating process.

Herein, the adhesive electrode 110 may be formed of PdIn3.

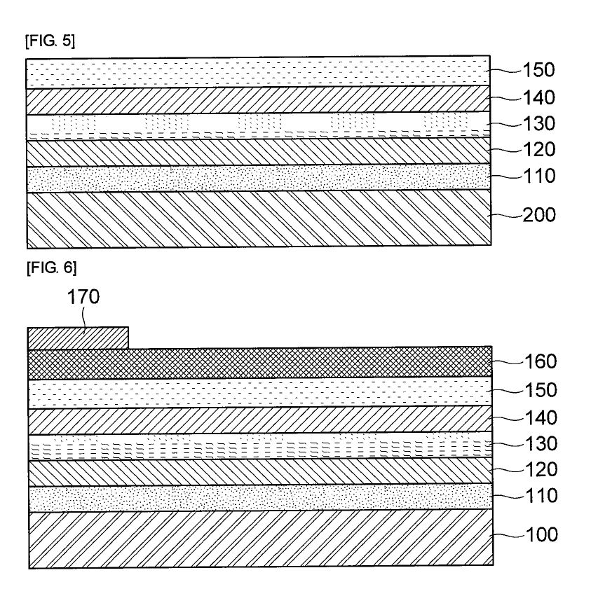

Thereafter, by irradiating the sapphire substrate 200 by a laser, as shown in FIG. 5, the sapphire substrate 200 is separated from the substrate 100 including the window layer 150. Herein, reaction caused by thermal transition produced by the laser in the sacrificial layer 210 results in reduction of bonding strength between the sacrificial layer 210 and the window layer 150, so that it is possible to separate the sapphire substrate 200 including the sacrificial layer 210 from the window layer 150.

Further, a surface of the window layer 150 is subjected to surface treatment to thereby remove residues of the sacrificial layer 210 that may exist on the surface of the window layer 150. Herein, as for a method of performing the surface treatment, a wet etching process, an ion milling, and so on may be exemplified. Thus, it is possible to prevent lowering of light absorption of the window layer 150 by the residues of the sacrificial layer 210.

Referring to FIG. 6, the second electrode 170 is formed on the window layer 150 exposed in accordance with the separation of the sapphire substrate 200 including the sacrificial layer 210. The second electrode 170 may be formed by forming a conductive film through deposition of Al, or Al and Ni, and then undergoing an etching process at a predetermined pattern.

In addition, before formation of the second electrode 170, a reflection prevention film 160 may be further formed on the window layer 150 so as to prevent reflection of light entering the window layer 150. Herein, the reflection prevention film 160 may be formed by deposition of MgF2.

Therefore, in the embodiment of the present invention, a thin-film including light absorption layer is formed on the sapphire substrate tolerable to high-temperature deposition, and then a thin-film including the light absorption layer is finally transferred on the final substrate, so as to form the solar cell, so that it is possible to prevent warpage of the substrate and overcome a limitation of the substrate used in the solar cell.

Further, a high-temperature deposition process is performed in the sapphire substrate having durability against the heat, so that it is possible to enough apply the top-plate deposition method which can use reasonably deposition equipment and is advantageous to a large-area substrate. CHEMICALLY BOUND METALLIC COMPOUNDS

Further, the first electrode can serve as an electrode, and allow the sapphire substrate and the substrate to be bonded to each other by reaction between a part of a metal of the first electrode and a metal of the conductive adhesive layer at a predetermined temperature, resulting in no need of separate metal film for combination between the sapphire substrate and the substrate, so that it is possible to reduce process costs.

The solar in accordance with the present invention is formed by performing a process for forming a thin-film on the sapphire substrate at a high-temperature, and then performing a transfer process for transferring the thin-film on a final substrate, so that it is possible to use the final substrate as a low-cost substrate, or a flexible substrate.

Also, the solar cell in accordance with the present invention is good for a large-area substrate, and is formed by the top-plate deposition method capable of using a low-priced manufacturing equipment, so that it is possible to reduce manufacturing costs of the solar cell, and implement a large-area substrate.

As described above, although the preferable embodiments of the present invention have been shown and described, it will be appreciated by those skilled in the art that substitutions, modifications and variations may be made in these embodiments without departing from the principles and spirit of the general inventive concept, the scope of which is defined in the appended claims and their equivalents.

What is claimed is:

1. A solar cell comprising:
a substrate;
an adhesive electrode disposed on the substrate;
a first electrode adhered to the substrate by the adhesive electrode;
a light absorption layer disposed on the first electrode;
a window layer disposed on the light absorption layer; and
a second electrode disposed on the window layer.

2. The solar cell of claim 1, wherein the adhesive electrode is made of a metal compound containing a metal forming the first electrode.

3. The solar cell of claim 1, wherein the first electrode is formed of Pd, and the adhesive electrode is formed of PdIn3.

4. The solar cell of claim 1, wherein the substrate is selected from one of a glass substrate and a plastic substrate.

5. The solar cell of claim 1, further comprising a buffer layer interposed between the light absorption layer and the window layer.

6. The solar cell of claim 1, further comprising a reflection prevention film interposed between the window layer and the second electrode.

7. A method for manufacturing a solar cell comprising the steps of:
forming a sacrificial layer on a sapphire substrate;
sequentially forming a window layer, a light absorption layer, and a first electrode on the sacrificial layer;
forming an adhesive electrode for adhering the first electrode to the substrate by heating a substrate including a conducive adhesive layer on the first electrode;
separating the sapphire substrate including the sacrificial layer from the window layer; and
forming a second electrode on the window layer exposed by the separation of the sapphire substrate.

8. The method of claim 7, wherein the first electrode is formed of Pd.

9. The method of claim 7, wherein the conductive adhesive layer is formed of In.

10. The method of claim 7, wherein the adhesive electrode is formed of PdIn3.

11. The method of claim 7, wherein the substrate is selected from one of a glass substrate and a plastic substrate.

12. The method of claim 7, wherein the step of separating the sapphire substrate including the sacrificial layer from the window is achieved by irradiating laser on the sapphire substrate and the bonded substrate.

13. The method of claim 7, further comprising a step of forming a buffer layer between the light absorption layer and the window layer.

14. The method of claim 7, further comprising a step of forming a reflection prevention film between the window layer and the second electrode.
